(19) United States
(12) Patent Application Publication
(10) Pub. No.: US 2008/0193636 A1
(43) Pub. Date: Aug. 14, 2008

(54) Vaporizing Device and Method for Vaporizing Coating Material

(75) Inventors: Lutz Gottsman, Kleinroehrsdorf (DE); Ulf Seyfert, Dresden (DE); Bernd-Dieter Wenzel, Grossharthau-Buehlau (DE); Reinhard Jaeger, Coswig (DE)

Correspondence Address: HESLIN ROTHENBERG FARLEY & MESITI PC, 5 COLUMBIA CIRCLE, ALBANY, NY, 12203, US

(73) Assignee: VON ARDENNE ANLAGENTECHNIK GMBH, Dresden (DE)

(21) Appl. No.: 11/568,329

(22) PCT Filed: Apr. 16, 2005
(86) PCT No.: PCT/DE05/00703

§ 371 Date: Feb. 23, 2007

(30) Foreign Application Priority Data
Apr. 27, 2004 (DE) 10-2004-020-843.3
Aug. 27, 2004 (DE) 10-2004-041-846.2

(51) Int. Cl. C23C 16/448; C23C 16/44; C23C 16/455; C23C 16/54

(52) U.S. Cl. 427/96.8; 118/719; 118/722

(57) ABSTRACT

A device for vaporizing coating material is disposed in a vacuum chamber as part of a deposition apparatus; the coating material being arranged in a crucible for vaporization purposes. The vaporizing device has an evaporation chamber that is connected, via a vacuum valve, to a loading chamber which can be evacuated while an evaporator is connected to the evaporation chamber at a vapor discharge end, i.e., the end facing the vacuum chamber, via a first vapor stop valve.

The invention relates to a vaporizing device for vaporizing coating material, which is arranged in a vacuum chamber as part of a deposition device, the coating material being arranged in a crucible that can be filled for vaporization purposes.

Furthermore, the invention relates to a method for vaporizing coating material in which the latter is used for deposition of a substrate in a vacuum chamber for a thermal vacuum deposition method.

Various deposition systems and deposition methods are known for thermal vapor deposition in a vacuum. For example, EP 0 735 157 discloses a method for vaporizing magnesium (Mg). According to the method, an Mg source is received in a vessel with a narrow opening and with a reflector plate arranged outside the opening. The vessel is heated to a temperature of 670° C. to 770° C., the Mg source being melted and the Mg being vaporized in the process. In the event of outflow, clusters and splashes are destroyed on the reflector plate at 500° C. or more, and the Mg vapor is guided by means of a duct heated to at least 500° C. extending from the outlet of the vessel to a substrate sheet positioned at the duct exit.

A distinction is generally made between systems with a static method and systems with a continuous method. Whereas in the static method the substrate supply is effected in a discontinuous manner and the regular substrate change enables regular stocking up with new coating material for a subsequent deposition process, in the continuous method a substrate is constantly conveyed through the deposition device. Such continuously depositing systems are generally used for coating band-shaped steel substrates with a bandwidth from the centimeter scale to the meter scale. So as not to interrupt the continuous process and to enable the commercial use of such a system, it is necessary here to stock up the deposition device with coating material to an extent that is sufficient to coat at least one substrate unit, for example an uninterrupted reel.

The vaporizing devices are generally integrated into the vapor deposition device and operate on a single-chamber principle. To this end, a vaporizing device is directly connected to the evaporation chamber in a vacuum chamber. If the stock of coating material is consumed in the vaporizing device, the entire vacuum chamber is ventilated and opened. After charging of the vaporizing device, the vacuum chamber is closed, evacuated and heated and the coating material is vaporized. The opening of the entire vacuum chamber means that the proportion of downtimes is relatively high, particularly due to long periods until adjustment of the process conditions.

It is also disadvantageous that in such a process sequence, residual gaseous coating material is deposited on the walls of the entire vacuum chamber during each instance of ventilation and cooling down, thus incurring significant costs for cleaning and maintenance. The necessary maintenance periods also increase the proportion of downtimes.

Therefore the aim of this invention is to provide a vaporizing device and method for vaporizing coating material for thermal vacuum deposition such that the downtimes are reduced and the cleaning and maintenance intervals are prolonged.

According to the invention, the aim is achieved by providing the vaporizing device with an evaporation chamber that is connected, via a vacuum valve, to a loading chamber which can be evacuated while an evaporator that takes up the crucible that can be filled with coating material is arranged in the evaporation chamber. Said evaporator is connected to the vaporization chamber at the vapor discharge end, i.e. the end facing the deposition system, via a first vapor stop valve.

As a loading chamber which can be evacuated can be connected to the evaporation chamber, ventilation of the evaporation chamber for stocking up with new coating material is not necessary, meaning that contamination of the vaporizing device from the environment can be reliably prevented and the maintenance requirement can be reduced as a result of this measure. According to the invention, for charging, through opening of the vacuum valve, the vacuum conditions of the evaporation chamber are extended to the evacuated loading chamber, which is provided with new coating material if applicable.

Charging of the evaporation chamber via a loading chamber in such an area that is not involved in the conveying of the vapor between the vaporizing and vapor deposition device only allows the arrangement of a vacuum-tight valve, as only air and process gases are to be shut off in this area and not vaporous coating material. This important feature is ensured due to the arrangement as per the invention of the evaporator within the evaporation chamber and due to the vapor conveying direction resulting from the dynamic system of vapor generation and vapor deposition, as the vaporous coating material remains almost completely in the evaporator and does not emerge into the evaporation chamber. For this purpose, according to claim 1, the evaporator forms a partial volume of the evaporation chamber in the evaporation chamber surrounding the crucible with the coating material.

This benefit is increased by a preferred embodiment in which the evaporator is provided with a second vapor stop valve at the charge end, i.e. the end facing the loading chamber. In this solution, it is ensured that the evaporator is operated in the locked state and physically separated from the evaporation chamber in a vapor-tight manner in such a way that no evaporated coating material can get into the evaporation chamber.

In every case, the arrangement according to the invention allows a significant reduction of the deposits of coating material on the outer walls of the evaporation chamber. Although the cooling down of the vaporizing device associated with re-stocking undoubtedly leads to material deposits, these are predominantly made on the walls of the evaporator, where they are vaporized again during the subsequent heating up of the evaporator, the alternative sealing of the evaporator at the charge end with a second vapor stop valve enabling even better sealing here.

To achieve this, the second vapor stop valve is not opened for charging with new coating material until after the evaporator has cooled down so that condensation is only formed in the evaporator, and is closed again before heating so that no vaporized material emerges into the surrounding evaporation chamber.

Another feasible benefit is that the evaporator has a tubular design. In this respect, the longitudinal extension of the tubular evaporator is large compared with the diameter. Furthermore, the internal diameter of the evaporator is adapted to the outer dimensions of a crucible that can be introduced therein, i.e. the evaporator closely surrounds the crucible. Consequently, the evaporator is as small as possible and can therefore be heated efficiently.

In one embodiment, provision is made for the second vapor stop valve of the evaporator to be designed as a locking plate. This locking plate locks the evaporator at the opening through which the crucible can run in, preferably in the position when the evaporator has already fully taken up the crucible.

The intention of this solution is for the evaporator to have exactly two physically separated openings, one opening being arranged at the vapor discharge end and a second opening being arranged opposite this, at the charge end, and therefore on the cold side. The first vapor stop valve is arranged at the opening at the vapor discharge end and the second one is arranged at the opening at the charge end, its function being fulfilled by a locking plate for more favorable charging. In the state in which the crucible is introduced into the evaporator, the crucible largely extends from one end to the other. The locking plate arranged at the loading chamber end on the crucible then largely corresponds to the base of the evaporator element that is, for example, designed as a hollow cylinder or a hollow prism.

In other favorable embodiments, provision is made for the loading chamber to be arranged either in a direction parallel to the longitudinal axis or parallel to the lateral axis of the two chambers towards the charge end of the evaporation chamber. In this way, straight-line travel of the crucible can be attained with the shortest distance of travel.

Another benefit is that a heating device is arranged around the evaporator, providing an even heat supply to the interior of the evaporator. The heating device is arranged as close as possible to the crucible and the coating material so that thermal radiation losses are minimized. In addition, the heating device is preferably electrically operable due to good adjustability, for example.

Other favorable variants of the invention are stated in that the evaporator is equipped with an evaporator conveying device and/or a crucible conveying device and, in addition, in that either the evaporator with the crucible by means of the evaporator conveying device or the crucible itself, by means of a crucible conveying device, is bidirectionally mobile in the arrangement direction of the loading chamber and is variably positioned in the evaporator with regard to the adopted resting position in the evaporation chamber and the loading chamber. In this way, depending on the size of the crucible or the evaporator, and depending on the spatial conditions, either the crucible alone or the evaporator with the crucible is to be precisely moved and positioned between the evaporation chamber and the loading chamber. The removal of the entire evaporator from the evaporation chamber, regardless of the presence of a crucible conveying device, is beneficial, for example for maintenance purposes or for the complete replacement of the evaporator.

Another embodiment stands out by virtue of the fact that, by means of the crucible conveying device, the crucible is bidirectionally mobile crosswise to the arrangement direction of the loading chamber and can be variably positioned with regard to the adopted resting position in the evaporator and loading chamber, as a result of which, for example, a correction or change of the position of one or more crucibles can take place in the respective chamber.

A further benefit arises from an embodiment in which the locking plate is arranged on the crucible or crucible conveying device and the opening of the evaporator at the charge end is lockable by means of the locking plate, which locks the evaporator in a vapor-tight manner at the loading chamber end at the same time as the positioning of the crucible.

Designs of the additional embodiment are carried out in such a way that the evaporator conveying device or crucible conveying device has slide rollers and/or slide rails for the mobile positioning of the evaporator and/or crucible in the loading chamber or that the evaporator and/or loading chamber has slide rollers and/or slide rails for the positioning of the crucible conveying device. By means of these slide rollers and/or slide rails, linear travel of the respective conveying device is carried out within the conveying area of the crucible, which extends from the loading chamber into the evaporator. Each conveying device designed in this way ensures largely smooth and precise conveying of the crucible.

A supplementary design of the additional embodiment is carried out in that a positioning unit is arranged on the crucible conveying device. The positioning unit is designed in such a way that the valve arranged between the loading chamber and the evaporator is unimpaired in terms of its vacuum-tight locking function. For this, the positioning device is greased with vacuum lubricants so that outgassing of the lubricants is prevented in vacuum operation. In addition, the positioning unit has a thermal load capacity in accordance with the evaporation temperatures.

A further benefit is that the evaporation chamber has a cooling device. The evaporation chamber is provided with the cooling device on the outside. The cooling device is arranged around the evaporation chamber. For cooling, coolant water or another coolant liquid flows through the cooling device. Therefore the heat in the vacuum chamber can be quickly dissipated and the cooling down process must be accelerated and controlled in a defined manner for the purpose of charging with a new coating substrate.

Other useful designs are represented by the execution of the loading chamber with an opening that can be locked in a vacuum-tight manner and/or at least one ventilation device. For charging the crucible with solid or liquid coating material, air can thus be admitted into the evacuated loading chamber by means of an upstream valve, so that pressure compensation exists at both ends of the lock that seals the opening. After this compensation, fast charging can be effected through the opening that can be locked in a vacuum-tight manner, without time-consuming dismantling and assembly work in the loading chamber.

If at least one other evaporator is assigned to other beneficial designs in the vaporizing device and, optionally, another loading chamber is assigned to this evaporator, the vaporizing device according to the invention is only suitable for charging in a continuous deposition process since, as described above, the vaporizing device does not have to be ventilated for stocking and only the interior of the evaporator that is optionally closed with the second vapor stop valve is connected to the vapor deposition device. The extent to which every evaporator is charged by means of a single loading chamber largely depends on the space available and the conveying system used for the crucible or evaporator.

Furthermore, several evaporators with simultaneous operation enable a high vaporization rate and therefore deposition of larger substrates or at higher conveying speeds.

The method-related solution to the inventive problem is attained by means of a method according to the characteristics of claim 20.

The principle of this solution is that in order to attain the vaporization rate required for the respective coating material whilst preventing the formation of condensation inside the evaporation chamber, it is useful for the coating material to be heated in the separate evaporator and the actual charging with new material, which necessitates the opening of the system, to be carried out in a separate volume, that of the loading chamber, which can be separated from the evaporation chamber in a vacuum-tight manner.

In this way, charging is possible without exposing to the atmospheric conditions the section of the vaporizing device in which the coating material is vaporized and that cannot be separated from the vapor deposition device in a vacuum-tight manner because of the vaporous coating material.

In addition to the above-mentioned benefits of the arrangement of an evaporator in terms of the physical restriction of condensation formation and the possibility of re-vaporization of this condensation, charging that is physically separated from vaporization reduces the actual charging process and positively influences the restoration and preservation of even process conditions due to the minimal intervention in the vaporizing device. It is also particularly expedient for this if even heating of the coating material on all sides is ensured by heating the coating material on all sides in the evaporator as a separate space in accordance with one embodiment of the method.

These benefits are especially utilized with the particularly favorable embodiment of the method according to the characteristics of claim 22, and in particular the formation of the unavoidable condensation is physically limited to the evaporator by means of the second vapor stop valve.

A variation of the method-related solution to the inventive problem is stated in that the evaporation process taking place in the evaporator with its associated charging via the loading chamber is divided into identical evaporation processes in other evaporators with associated charging operations in other loading chambers. With this embodiment, continuous charging with new coating material and a particularly even introduction of vapor into the vapor deposition device is ensured, as interruptions or fluctuations are to be compensated by means of the other evaporators.

In this respect, it proves to be beneficial if the divided evaporation processes are executed sequentially and/or simultaneously and/or with a time overlap.

In another embodiment, the evaporation chamber is beneficially cooled for charging the crucible with the coating material. The cooling down of the evaporation chamber that is required before the environmental conditions are extended to the loading chamber is carried out in this embodiment after the heating device is switched off through heat exchange with the actively cooled inner wall of the evaporation chamber, for example by means of circulating liquid cooling. Cooling down is thus significantly accelerated, and can be controlled in a targeted manner via the cooling process and/or the coolant.

Special embodiments are advantageously realized in that, for charging the crucible with the coating material, a gas is introduced into the evaporation chamber and/or the evaporator and/or a gas is introduced into the loading chamber in a metered manner for opening the loading chamber. If a gas is injected into the loading chamber in a metered manner for opening the loading chamber, the pressure compensation between the loading chamber and the environment is also accelerated and structured in a controllable manner. Metering for this is carried out in accordance with the temperature of the gas that expands during injection and cools down as a result of the expansion. Air is a possibility for the injected gas, for example.

It is also beneficial if the vacuum and the temperature and the opening and closing of the valves and the crucible conveying device and the respective gas introduction are controlled by means of a control device as provided for in another method-related design. The external conditions for operation at the vaporization rate required for the respective coating material are thus to be adjusted in a targeted manner. Measured values recorded by sensors are gathered in the control device. By means of the control device, the respective conditions are pre-selected and realized in an automated or manual manner.

The invention is described in more detail below on the basis of an execution example. There are two drawings:

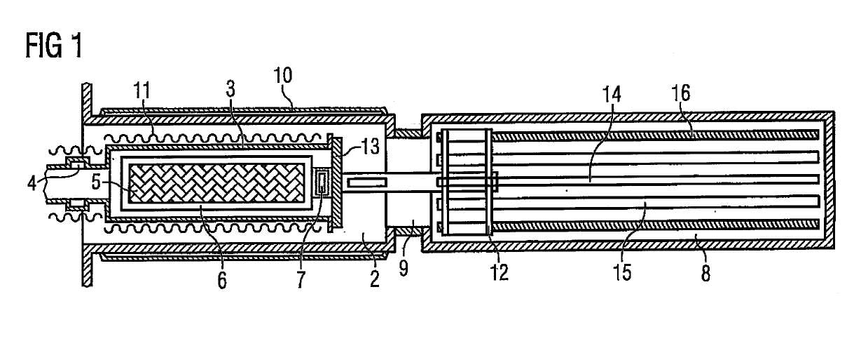

FIG. 1 shows a horizontal cross-section of a vaporizing device 1 according to the invention in the vaporizing state and

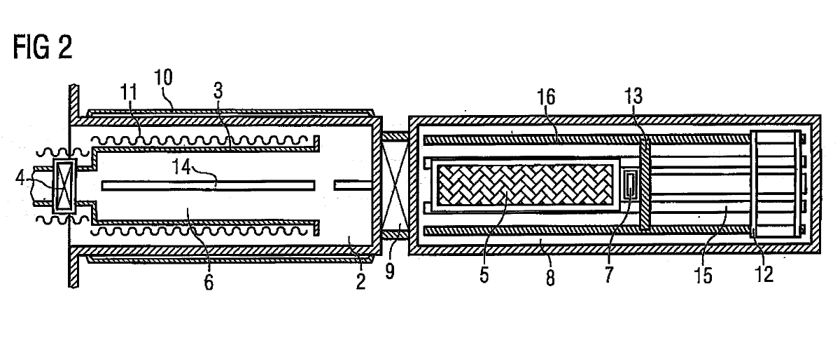

FIG. 2 shows a horizontal cross-section of a vaporizing device 1 according to the invention in the charging state.

### Regarding the Object:

FIG. 1 and FIG. 2 show a vaporizing device 1 according to the invention with an evaporation chamber 2, an evaporator 3 arranged in this evaporation chamber 2, a first vapor stop valve 4 arranged at the vapor discharge end, a crucible 6 that can be filled with the coating material 5 and a crucible conveying device 7 as well as a loading chamber 8 and a vacuum valve 9 inserted between the loading chamber 8 and the evaporation chamber 2.

The elongated cuboidal loading chamber 8 and the evaporation chamber 2 can be evacuated, the loading chamber 8 having at the top an unshown opening that can be locked in a vacuum-tight manner for charging the crucible 6 into the loading chamber 8 (FIG. 2). Furthermore, the evaporation chamber 2 is surrounded on the outside by a cooling device 10 through which water flows as a coolant liquid.

The evaporator 3 is designed as a tubular elongated channel that has a flange at both ends. The evaporator 3 therefore has two opposing openings, the first vapor stop valve 4 being applied at the opening at the vapor discharge end facing the vapor deposition chamber and the second opposing opening being used for introducing the crucible 6. A suitable heating device 11 is applied around the evaporator element 3. The crucible 6 that is filled with the coating material 5, for example solid magnesium, rests on a crucible conveying device 7. This has, at the vapor discharge end, a protrusion on which the crucible 6 rests. The positioning unit 12 designed as a sliding base is arranged at the loading chamber end. A locking plate 13 whose diameter corresponds to the opening of the evaporator 3 at the loading chamber end is applied between the crucible support and the positioning unit 12. A central rail 14 is arranged on the floor of the evaporator 3 along the length, on which rail the protrusion of the crucible conveying device 7 is supported via bearing rollers arranged on its underside. Such a central rail 14 is also applied in the loading chamber 8, continuing the travel of the projection. In this respect, the function of the vacuum valve 9 arranged between the loading chamber 8 and the evaporation chamber 2 is not influenced by the continuation of the rail. The positioning unit 12 is mounted on two rails 15 arranged in the loading chamber 8 with several rollers. Movements are effected via a spindle drive with a spindle 16 that travels lengthwise through the loading chamber.

As FIG. 1 shows, the opening of the evaporator 3 at the loading chamber end is locked by means of the locking plate 13 in the state in which the crucible 6 is introduced into the evaporator 3. The lock is vapor-tight so that essentially, no vaporized coating material 5 from the evaporator element 3 can penetrate the evaporation chamber 2 or the loading chamber 8.

### Regarding the Method:

FIG. 1 shows the vaporizing device 1 according to the invention in the vaporizing state. To achieve this, the crucible 6 resting on the crucible conveying device 7 is introduced into the evaporator 3 from the charging position shown in FIG. 2 after closure of the charge opening, evacuation of the loading chamber 8 at the same pressure as in the evaporation chamber 2 of greater than or equal to 10⁻³ mbar, and opening of the vacuum valve 9. In this process, the opening of the evaporator 3 at the loading chamber end is locked in a vapor-tight manner by means of the locking plate 13 of the crucible conveying device 7.

In the vaporization position shown in FIG. 1, the heating device 11 arranged around the evaporator 3 is now activated and the coating material 5, for example solid magnesium, is heated to around 600° C. In this process, the solid magnesium vaporizes to form gaseous magnesium. The first vapor stop valve 4 is opened and the gaseous coating material 5 emerges and is taken away for deposition. A process pressure of around 10⁻¹ mbar is set in the evaporator 3. To achieve this, the evaporator 3 is heated up under the process conditions in such a way that the preferred vaporization rate is achieved in the crucible 6 filled with coating material 5 whilst avoiding the formation of condensation inside the evaporator 3. The vacuum and the temperature and opening and closing of the first vapor stop valve 4 are controlled by means of a computer-aided control device.

For charging, the evaporator 3 is cooled down in such a way that a minimum vaporization rate is achieved that enables opening of the evaporator 3 to the environment in the evaporation chamber 2 after closure of the first vapor stop valve 4 without gaseous coating material 5 entering the environment outside the evaporator 3. Cooling down initially takes place through deactivation of the heating device 11 and through cooling of the evaporation chamber 2 by means of the circulating water cooling of the cooling device 10. The heat compensation is largely carried out via thermal radiation and is conveyed via the matter in the evaporation chamber 2 and dissipated by the cooling water.

Next, the crucible 6 is brought from the crucible conveying device 7 into the charging position (FIG. 2) and the vacuum valve 9 is closed. To open the charge opening, air is introduced to the loading chamber in a slightly metered manner for pressure compensation and, when pressure compensation is attained, the coating opening is opened.

### LIST OF NUMERALS

1 Vaporizing device
2 Evaporation chamber
3 Evaporator
4 First vapor stop valve
5 Coating material
6 Crucible
7 Conveying device
8 Loading chamber
9 Vacuum valve
10 Cooling device
11 Heating device
12 Positioning unit
13 Locking plate (second vapor stop valve)
14 Central rail
15 Rails
16 Spindle

1. Vaporizing device for vaporizing coating material, which device is arranged in a vacuum chamber as part of a deposition device, the coating material being arranged in a crucible that can be filled for vaporization purposes, wherein the vaporizing device has an evaporation chamber connected, via a vacuum valve, to a loading chamber which can be evacuated while an evaporator that accommodates the crucible filled with coating material is arranged in the evaporation chamber, the evaporator being connected to vapor disposition chamber at a vapor discharge end facing the vapor deposition chamber, via a first vapor stop valve.

2. Vaporizing device according to claim 1, wherein the evaporator is provided with a second vapor stop valve at a charge end facing the loading chamber.

3. Vaporizing device according to claim 2, wherein the second vapor stop valve of the evaporator comprises a locking plate.

4. Vaporizing device according to claim 1, wherein loading chamber is arranged in a direction parallel to a longitudinal axis of the evaporation chamber at the charge end of the evaporation chamber.

5. Vaporizing device according to claim 1, wherein the loading chamber is arranged in a direction parallel to a lateral axis of the evaporation chamber at the charge end of the evaporation chamber.

6. Vaporizing device according to claim 1, wherein a heating device is arranged around the evaporator.

7. Vaporizing device according to claim 1, wherein the evaporator is equipped with an evaporator conveying device and/or a crucible conveying device.

8. Vaporizing device according to claim 7, wherein the evaporator with the crucible, is displaceable by the evaporator conveying device bidirectionally between adopted resting positions in the evaporation chamber and in the loading chamber.

9. Vaporizing device according to claim 7, wherein the crucible is displaceable by the crucible conveying device bidirectionally between adopted resting positions in the evaporator and in the loading chamber.

10. Vaporizing device according to claim 9, wherein the crucible is bidirectionally mobile crosswise to an arrangement direction of the loading chamber and can be variably positioned with regard to the adopted resting positions in the evaporator and loading chamber.

11. Vaporizing device according to claim 7, wherein a locking plate is arranged on the crucible or the crucible conveying device and an opening of the evaporator at a charge end is lockable by means of the locking plate.

12. Vaporizing device according to claim 7, wherein the crucible conveying device and/or the evaporator conveying device has slide rollers and/or slide rails for mobile positioning of the crucible and/or evaporator in the loading chamber.

13. Vaporizing device according to claim 7, wherein the evaporator and/or loading chamber has slide rollers and/or slide rails for positioning of the crucible conveying device.

14. Vaporizing device according to claim 7, wherein a positioning unit is arranged on the crucible conveying device.

15. Vaporizing device according to claim 1, wherein the evaporation chamber has a cooling device.

16. Vaporizing device according to claim 1, wherein the loading chamber has an opening that can be locked in a vacuum-tight manner for charging the crucible.

17. Vaporizing device according to claim 1, wherein the loading chamber has at least one ventilation device.

18. Vaporizing device according to claim 1, wherein at least one additional evaporator is arranged in the vaporizing device.

19. Vaporizing device according to claim 18, wherein an additional loading chamber is assigned to the additional evaporator.

20. Method for vaporizing coating material in a vaporizing device in which, in an evacuated evaporation chamber of the vaporizing device, the coating material present in a crucible is heated and vaporized and the evaporation chamber is cooled down after end of vaporization process in order to carry out charging with new coating material, wherein the coating material is indirectly heated via heating of an evaporator arranged in the evaporation chamber, the evaporator forms an evacuated partial volume of the evaporation chamber and surrounds the crucible with the coating material, the evaporator is cooled down again after end of evaporation process, charging of the evaporation chamber with new coating material is carried out via an evacuated loading chamber connected to the evaporation chamber through opening and closing of a vacuum-tight valve and separated in a vacuum-tight manner, and charging of the crucible is carried out in the separate and ventilated loading chamber.

21. Method according to claim 20, wherein the coating material present in the crucible in the evaporator is heated on all sides and vaporized.

22. Method according to claim 21, wherein present coating material is heated and generated vapor of the coating material is taken away from the evaporator via a first vapor tight vapor stop valve until vaporization has finished, removal of this vapor is then prevented by the vapor-tight first vapor stop valve, heating of the evaporator is subsequently interrupted and the evaporation chamber is cooled down, interior of an evacuated loading chamber is then physically connected to the evacuation chamber via a connecting vacuum valve through its effected opening and vacuum is compensated so that after opening a second vapor stop valve of the evaporator situated opposite the vacuum valve, the crucible is taken up in the loading chamber and the loading chamber is charged with coating material after closure of the vacuum valve that can be locked in a vacuum-tight manner and ventilation of the loading chamber, after evacuation of the interior of the loading chamber, the interior of the loading chamber is connected to the evaporator through reopening of the vacuum valve and the crucible with the new coating material is positioned in the evaporator and, after locking the second vapor stop valve of the evaporator, heating of the new coating material is carried out in the evaporator.

23. Method according to claim 20, wherein the crucible is transferred into the loading chamber together with the evaporator.

24. Method according to claim 20, wherein the crucible or the evaporator is moved between the evaporation chamber and the loading chamber by a conveying device.

25. Method according to claim 20, wherein the vaporization process taking place in the evaporator with associated charging via the loading chamber is divided into identical evaporation processes in other evaporators with associated charging operations in other loading chambers.

26. Method according to claim 25, wherein the divided evaporation processes are executed sequentially and/or simultaneously and/or with a time overlap.

27. Method according to claim 20, wherein the evaporation chamber is cooled for charging of the crucible with the coating material.

28. Method according to claim 20, wherein for charging the crucible with the coating material, a gas is introduced into the evaporation chamber and/or the evaporator.

29. Method according to claim 20, wherein a gas is introduced into the loading chamber in a metered manner for opening the loading chamber.

30. Method according to claim 20, wherein a control device is used to control vacuum and temperature, the opening and closing of the valve, and a crucible conveying device and respective gas introduction.
